(19) United States
(12) Patent Application Publication
(10) Pub. No.: US 2026/0201885 A1
(43) Pub. Date: Jul. 16, 2026

(54) ELECTRIC COMPRESSOR AND METHOD FOR PRODUCING SAME

(71) Applicant: SANDEN CORPORATION, Isesaki-shi, Gunma (JP)

(72) Inventors: Shigeyuki MATSUMOTO, Isesaki-shi, Gunma (JP); Toru ITO, Isesaki-shi, Gunma (JP); Nawja WONDER, Isesaki-shi, Gunma (JP)

(73) Assignee: SANDEN CORPORATION, Isesaki-shi, Gunma (JP)

(21) Appl. No.: 19/136,084

(22) PCT Filed: Dec. 25, 2023
(86) PCT No.: PCT/JP2023/046386

§ 371 Date: Jun. 5, 2025

(30) Foreign Application Priority Data
Jan. 20, 2023 (JP) 2023-007575

(51) Int. Cl. F04C 23/02; F04C 18/02; H05K 7/14

(52) U.S. Cl. CPC F04C 23/02; F04C 18/0215; H05K 7/1417; F04C 2230/60; F04C 2240/805; F04C 2240/808

(57) ABSTRACT

An electric compressor 1 is configured such that a board 51 to which a switching element 5 is connected is assembled to a housing 11, and includes a fixing plate 57 disposed between the switching element 5 and the board 51 and having spring properties. The fixing plate 57 is held by the switching element 5, and presses the switching element 5 against the housing 11 in a state of the board 51 being assembled to the housing 11. The fixing plate 57 has a spring portion for pressing the switching element 5 against the housing 11 and a positioning portion engaged with a run-through hole of the switching element 5.

### CROSS-REFERENCE TO RELATED APPLICATIONS

This application is a U.S. National Stage Patent Application under 37 U.S.C. § 371 of International Patent Application No. PCT/JP 2023/046386, filed on Dec. 25, 2023, which claims the benefit of Japanese Patent Application No. JP 2023-007575, filed on Jan. 20, 2023, the disclosures of each of which are incorporated herein by reference in their entirety.

### TECHNICAL FIELD

The present invention relates to an electric compressor in which a board to which a switching element is connected is assembled to a housing, and a method for producing the electric compressor.

### BACKGROUND ART

For example, an inverter-integrated electric compressor in which an inverter is provided in a housing has been used as a refrigerant compressor used in an air conditioning device of an electric vehicle. In this case, the housing of the electric compressor is formed with a motor chamber accommodating a motor and an inverter accommodation portion partitioned from the motor chamber and accommodating the inverter.

In addition, there has been adopted a structure in which a switching element (IGBT or the like) of the inverter is provided on a partition wall between the motor chamber and the inverter accommodation portion, the partition wall is used as a heat sink, and the switching element is fixed to the partition wall by pressing the switching element against the partition wall (heat sink), for example, by a leaf spring described in Patent Literature 1 and is cooled with low-temperature refrigerant flowing on the motor chamber side with respect to the partition wall (see, for example, Patent Literature 1).

### CITATION LIST

### Patent Literature

Patent Literature 1: Japanese Patent No. 5644706
Patent Literature 2: WO2021/118135

### SUMMARY OF INVENTION

### Problems to be Solved by Invention

Here, in order to improve workability when the board and the switching element forming the inverter are assembled to the housing, there has been considered a method in which the board and the switching element are sub-assembled and integrated in advance and the integrated board and switching element are assembled to the housing (see, for example, Patent Literature 2).

However, since the conventional method has a structure in which a spring for pressing the switching element against the housing is assembled to a resin frame in advance and the resin frame, the housing, and the switching element are integrally assembled, there is a problem that the number of components is great and the structure is also complicated.

The present invention has been made to solve these conventional technical problems, and is intended to provide an electric compressor configured such that a board, a switching element, and a fixing plate for pressing the switching element against a housing can be integrated into an assembly with a simple configuration and the assembly can be assembled to the housing and a method for producing the electric compressor.

### Solution to Problems

An electric compressor of the invention of claim 1 is configured such that a board to which a switching element is connected is assembled to a housing, which includes a fixing plate disposed between the switching element and the board and entirely or at least partially having spring properties. The fixing plate is held by the switching element, and presses the switching element against the housing in a state of the board being assembled to the housing.

An electric compressor of the invention of claim 2 is the electric compressor of the above-described invention, in which the board has a board fastening portion for fastening the board to the housing, and the fixing plate has a fixing plate fastening portion formed at a position coincident with the board fastening portion, a spring portion for biasing the switching element toward the housing, and a positioning portion engaged with the switching element.

An electric compressor of the invention of claim 3 is the electric compressor of the above-described invention, in which the positioning portion is formed so as to protrude from the spring portion, and the fixing plate is held by the switching element by engaging the positioning portion with a run-through hole of the switching element.

An electric compressor of the invention of claim 4 is the electric compressor of the above-described invention, in which a plurality of the switching elements is connected to the board, and the fixing plate has a plurality of the spring portions biasing the switching elements respectively, the positioning portion formed in each spring portion, and a terminal passing portion through which terminals of the switching elements pass.

A method for producing an electric compressor according to the invention of claim 5 is for assembling a board, to which a switching element is connected, to a housing, which includes preparing a fixing plate having a spring portion for biasing the switching element toward the housing, a positioning portion engaged with the switching element, a terminal passing portion through which a terminal of the switching element passes, and a fixing plate fastening portion, disposing the fixing plate between the switching element and the board, and integrally assembling the switching element, the fixing plate, and the board by connecting the terminal of the switching element, which has passed through the terminal passing portion of the fixing plate, to the board in a state of the positioning portion of the fixing plate being engaged with a run-through hole of the switching element and the fixing plate fastening portion of the fixing plate being coincident with a board fastening portion of the board.

In addition to the above-described invention, a method for producing the electric compressor according to the invention of claim 6 further includes, after the assembled switching element, fixing plate, and board have been disposed in the housing with the switching element on the housing side, inserting a fastener into the board fastening portion and the fixing plate fastening portion, and assembling the board and the fixing plate to the housing by co-fastening by screwing the fastener into the housing, and pressing the switching element against the housing by the spring portion of the fixing plate.

A method for producing the electric compressor according to the invention of claim 7 is the method of the above-described invention, in which a load of pressing the switching element against the housing is adjusted by changing the free length of the spring portion of the fixing plate or adjusting the rigidity of the fixing plate.

### Effects of Invention

According to the present invention, in the electric compressor in which the board to which the switching element is connected is assembled to the housing, the fixing plate entirely or at least partially having the spring property and disposed between the switching element and the board is provided, and the switching element is pressed against the housing in a state of the fixing plate being held by the switching element and the board being assembled to the housing. Thus, the switching element, the fixing plate, and the board can be integrally assembled in advance with a simple configuration, these assembled components can be assembled to the housing, and in the assembled state, the switching element can be pressed against the housing by the fixing plate.

As a result, it is possible to improve workability when the board to which the switching element is connected is assembled to the housing while reducing the number of components and a cost.

In this case, since the fixing plate fastening portion formed at the position coincident with the board fastening portion for fastening the board to the housing is formed in the fixing plate, and the spring portion for biasing the switching element toward the housing and the positioning portion engaged with the switching element are provided in the fixing plate, the board and the fixing plate can be fastened to the housing with the fastener without any trouble, and the pressing of the switching element against the housing by the fixing plate and the holding of the fixing plate by the switching element can be stably performed.

Since the positioning portion of the fixing plate is formed so as to protrude from the spring portion, and the positioning portion is engaged with the run-through hole of the switching element, the fixing plate is held by the switching element. Thus, the pressing of the switching element against the housing by the fixing plate and the holding of the fixing plate by the switching element can be performed with a simple configuration.

In a case where the plurality of switching elements is connected to the board, the plurality of spring portions for biasing the switching elements is formed in the fixing plate, and the positioning portions are formed in the spring portions. Thus, each switching element can be stably pressed against the housing. Moreover, since the terminal passing portion through which the terminals of each switching elements pass is provided in the fixing plate, the terminals of the switching elements can be connected to the board without any trouble.

Furthermore, since the load of pressing the switching element against the housing is adjusted by changing the free length of the spring portion of the fixing plate or adjusting the rigidity of the fixing plate, the switching element can be safely and stably pressed against the housing with a simple configuration.

### BRIEF DESCRIPTION OF DRAWINGS

FIG. 1 is a schematic sectional view of an electric compressor of an embodiment to which the present invention is applied.

FIG. 2 is a perspective view of the electric compressor of FIG. 1.

FIG. 3 is a perspective view of the electric compressor of FIG. 1 in a state of a lid member being detached.

FIG. 4 is an exploded perspective view of the electric compressor of FIG. 1.

FIG. 5 is a perspective view of an inverter of the electric compressor of FIG. 1 as viewed from the front surface thereof.

FIG. 6 is a perspective view of the inverter of FIG. 5 as viewed from the back surface thereof.

FIG. 7 is a side view of the inverter of FIG. 5.

FIG. 8 is an exploded perspective view of the inverter of FIG. 5.

FIG. 9 is an enlarged sectional view of a switching element of the inverter of FIG. 5.

FIG. 10 is an enlarged perspective view of a main portion of FIG. 9.

FIG. 11 is a perspective view of an inverter accommodation portion formed in a housing of the electric compressor of FIG. 1.

FIG. 12 is an exploded perspective view for describing a positional relationship between bolts for fastening the inverter of FIG. 5 to the housing and the inverter.

FIG. 13 is a perspective view of the inverter in a state of the bolts of FIG. 12 being inserted as viewed from the front surface thereof.

FIG. 14 is a perspective view of the inverter of FIG. 13 as viewed from the back surface thereof.

FIG. 15 is a side view of the inverter of FIG. 13.

FIG. 16 is an exploded perspective view for describing a positional relationship between the bolts for fastening the inverter and the lid member of the electric compressor of FIG. 1 to the housing, the inverter, and the lid member.

### DESCRIPTION OF EMBODIMENTS

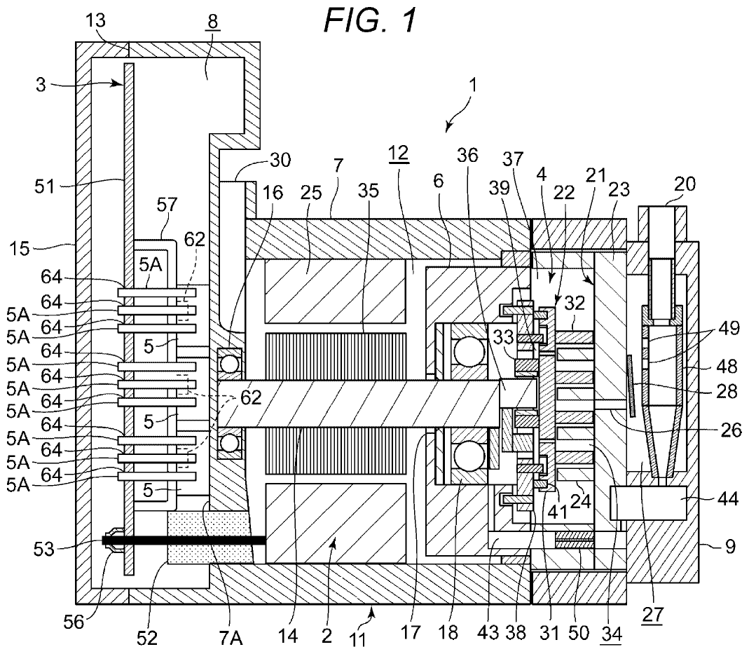

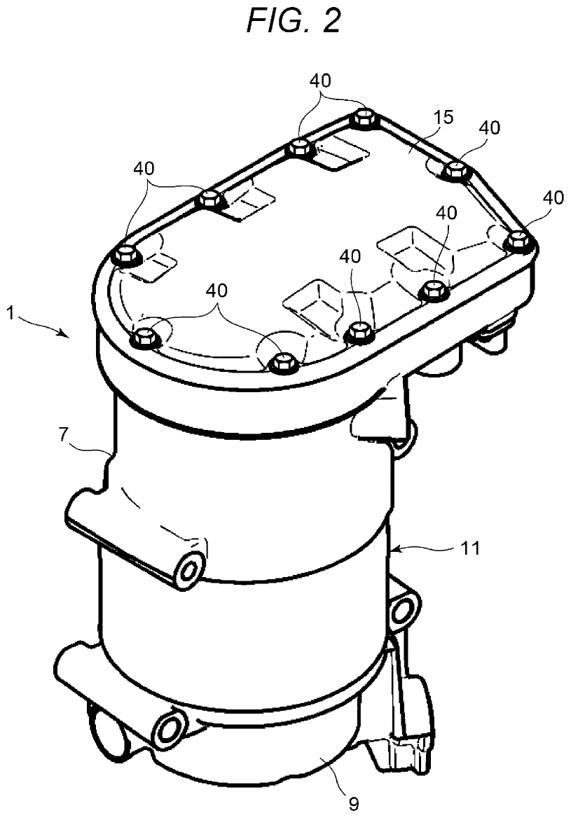

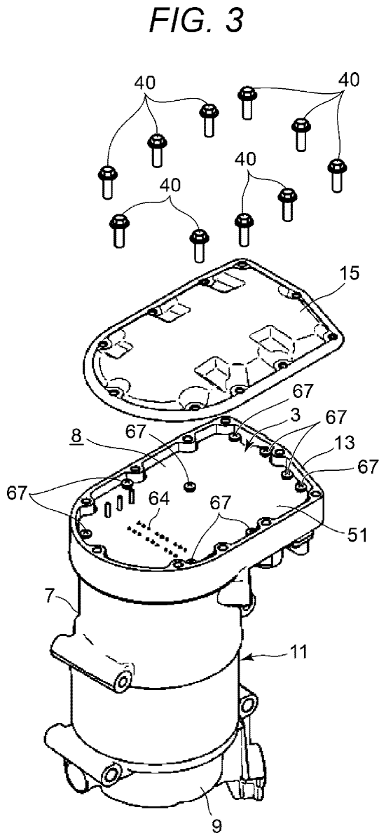

Hereinafter, embodiments of the present invention will be described in detail with reference to the drawings. FIG. 1 is a schematic sectional view of an electric compressor 1 according to an embodiment to which the present invention is applied, FIG. 2 is a perspective view of the electric compressor 1, and FIG. 3 is a perspective view of a state of a lid member 15 being detached.

### (1) Configuration of Electric Compressor 1

The electric compressor 1 of the embodiment is used, for example, in a refrigerant circuit of an air conditioner for an electric vehicle, and sucks, compresses, and discharges refrigerant as working fluid for the air conditioner to a discharge pipe.

The electric compressor 1 is a so-called horizontal inverter-integrated scroll electric compressor including a three-phase electric motor 2 as an example of a motor, an inverter 3 that operates the electric motor 2, and a scroll compression mechanism 4 as a compression mechanism driven by the electric motor 2.

The electric compressor 1 of the embodiment includes a main casing 7 accommodating the electric motor 2 and a center casing 6 therein, an inverter accommodation portion 8 formed on one end side of the main casing 7 and accommodating the inverter 3 therein, and a rear casing 9 attached to the other end side of the main casing 7. The main casing 7 and the rear casing 9 are all made of metal (aluminum in the embodiment), and are integrally joined to form a housing 11 of the electric compressor 1 of the embodiment.

In the main casing 7, a motor chamber 12 accommodating the electric motor 2 is formed, and one end surface of the motor chamber 12 is basically closed by an end wall 7A of the main casing 7. The end wall 7A serves as a partition wall defining the motor chamber 12 and the inverter accommodation portion 8. The other end surface of the motor chamber 12 is opened, and the center casing 6 is accommodated in the opening after the electric motor 2 has been accommodated in the opening. In addition, a sub bearing 16 for rotatably supporting one end portion of a drive shaft 14 of the electric motor 2 is attached to the inner surface (motor chamber 12 side) of the end wall 7A.

The center casing 6 is opened on a side (other end side) opposite to the electric motor 2. After a movable scroll 22, which will be described below, of the scroll compression mechanism 4 has been accommodated in the opening, the rear casing 9 to which a fixed scroll 21, which will also be described below, of the scroll compression mechanism 4 is fixed is fixed to the main casing 7 to thereby close the opening.

Moreover, a through-hole 17 into which the other end portion of the drive shaft 14 of the electric motor 2 is inserted is opened in the center casing 6, and a main bearing 18 rotatably supporting the other end portion of the drive shaft 14 on the scroll compression mechanism 4 side is attached on the scroll compression mechanism 4 side of the through-hole 17 in the center casing 6.

The electric motor 2 includes a stator 25 around which a coil is wound and which is fixed to the inner side of the peripheral wall of the main casing 7, and a rotor 35 rotating inside the stator 25. Then, for example, DC voltage from a battery (not shown) of the vehicle is converted into three-phase AC voltage by the inverter 3, and the three-phase AC voltage is supplied to the coil of the stator 25 of the electric motor 2, and accordingly the rotor 35 is rotationally driven. In addition, the drive shaft 14 is fixed to the rotor 35.

Moreover, a suction port 30 is formed in the main casing 7, and refrigerant sucked through the suction port 30 passes through the electric motor 2 in the main casing 7, then flows into the center casing 6, and is sucked into a suction portion 37 outside the scroll compression mechanism 4. As a result, the end wall 7A and the electric motor 2 are cooled with the sucked refrigerant. Moreover, it is configured in such a manner that refrigerant compressed by the scroll compression mechanism 4 is discharged from a discharge chamber 27 to be described below into the discharge pipe of the refrigerant circuit (not shown) outside the housing 11 through a discharge port 20 formed in the rear casing 9.

The scroll compression mechanism 4 includes the above-described fixed scroll 21 and movable scroll 22. The fixed scroll 21 integrally includes a disk-shaped end plate 23, and a wrap 24 erected on a surface (one surface) of the end plate 23, the wrap 24 having an involute shape or a spiral shape formed of a curve close to the involute shape and being fixed to the rear casing 9 with the surface, on which the wrap 24 is erected, of the end plate 23 facing the center casing 6. A discharge hole 26 is formed in the center of the end plate 23 of the fixed scroll 21, and the discharge hole 26 communicates with the discharge chamber 27 in the rear casing 9. In the figure, a reference numeral 28 denotes a discharge valve provided at the opening of the discharge hole 26 on the back surface (other surface) side of the end plate 23.

The movable scroll 22 is a scroll that revolves relative to the fixed scroll 21, and integrally includes a disk-shaped end plate 31, a wrap 32 erected on a surface (one surface) of the end plate 31, the wrap 32 having an involute shape or a spiral shape formed of a curve close to the involute shape, and a boss 33 protruding from the center of the back surface (other surface) of the end plate 31. The movable scroll 22 is disposed in such a manner that the wrap 32 faces and meshes with the wrap 24 of the fixed scroll 21 with the protruding direction of the wrap 32 facing the fixed scroll 21, and a compression chamber 34 is formed between the wraps 24, 32.

That is, the wrap 32 of the movable scroll 22 faces the wrap 24 of the fixed scroll 21, and meshes with the wrap 24 of the fixed scroll 21 in such a manner that the distal end of the wrap 32 is in contact with the surface of the end plate 23 and the distal end of the wrap 24 is in contact with the surface of the end plate 31, and an eccentric portion 36 provided at the other end of the drive shaft 14 so as to be eccentric to the axis is fitted in the boss 33 of the movable scroll 22. In addition, it is configured in such a manner that when the drive shaft 14 is rotated together with the rotor 35 of the electric motor 2, the movable scroll 22 revolves relative to the fixed scroll 21 without rotating on its axis.

Since the movable scroll 22 eccentrically revolves relative to the fixed scroll 21, the eccentric direction and contact position of each of the wraps 24, 32 move during rotation, and the compression chamber 34 having sucked refrigerant from the above-described suction portion 37 on the outside is gradually narrowed while moving inward. As a result, the refrigerant is compressed and finally discharged from the center discharge hole 26 to the discharge chamber 27 through the discharge valve 28.

In FIG. 1, a reference numeral 38 denotes a circular ring-shaped thrust plate. The thrust plate 38 divides a back pressure chamber 39 formed between the back surface of the end plate 31 of the movable scroll 22 and the center casing 6 and the suction portion 37 outside the scroll compression mechanism 4, is located outside the boss 33, and is interposed between the center casing 6 and the movable scroll 22. Moreover, a reference numeral 41 denotes a sealing member attached to the back surface of the end plate 31 of the movable scroll 22 and contacting the thrust plate 38. The sealing member 41 and the thrust plate 38 divide the back pressure chamber 39 and the suction portion 37.

Further, a reference numeral 48 denotes a centrifugal oil separator attached in the discharge chamber 27 of the rear casing 9. The oil separator 48 separates lubricating oil mixed in refrigerant discharged from the scroll compression mechanism 4 into the discharge chamber 27, from the refrigerant. The oil separator 48 is formed with an inlet 49, and refrigerant containing oil, which flows in through the inlet 49, swirls in the oil separator 48. The oil is separated by the centrifugal force at this time, and the refrigerant flows from an outlet at the upper end toward the discharge port 20, and is discharged to the discharge pipe as described above.

The rear casing 9 below the oil separator 48 is formed with an oil reservoir 44, and the oil separated from the refrigerant by the oil separator 48 flows into the oil reservoir 44 from the lower end of the oil separator 48. In the drawing, a reference numeral 43 denotes a back pressure passage formed from the rear casing 9 to the center casing 6. The back pressure passage 43 is a path which causes the oil separator 48 in the discharge chamber 27 (discharge side of the scroll compression mechanism 4) in the rear casing 9 to communicate with the back pressure chamber 39, and has an orifice 50 in the embodiment. As a result, the back pressure chamber 39 is configured in such a manner that discharge pressure adjusted and reduced by the orifice 50 of the back pressure passage 43 is supplied to the back pressure chamber 39 together with the oil in the oil reservoir 44, which has been separated by the oil separator 48.

The pressure (back pressure) in the back pressure chamber 39 generates a back pressure load which presses the movable scroll 22 against the fixed scroll 21. Under the back pressure load, the movable scroll 22 is pressed against the fixed scroll 21 against compression reaction force from the compression chamber 34 of the scroll compression mechanism 4, the contact between the wraps 24, 32 and the end plates 31, 23 is maintained, and refrigerant can be compressed in the compression chamber 34.

On the other hand, one end side of the inverter accommodation portion 8 is opened (in FIGS. 1 and 3 and other figures, indicated by a reference numeral 13), and the opening 13 is openably closed with the lid member 15. After the inverter 3 has been housed in the inverter accommodation portion 8 and the inverter 3 has been housed in the inverter accommodation portion 8, the lid member 15 is fastened to the main casing 7 (housing 11) with a bolt (10 bolts in the embodiment) 40 as a fastener as shown in FIG. 3 and attached as shown in FIG. 2. In this state, the inverter accommodation portion 8 is closed with the lid member 15.

### (2) Structure of Inverter 3 and Peripheral Structure Thereof

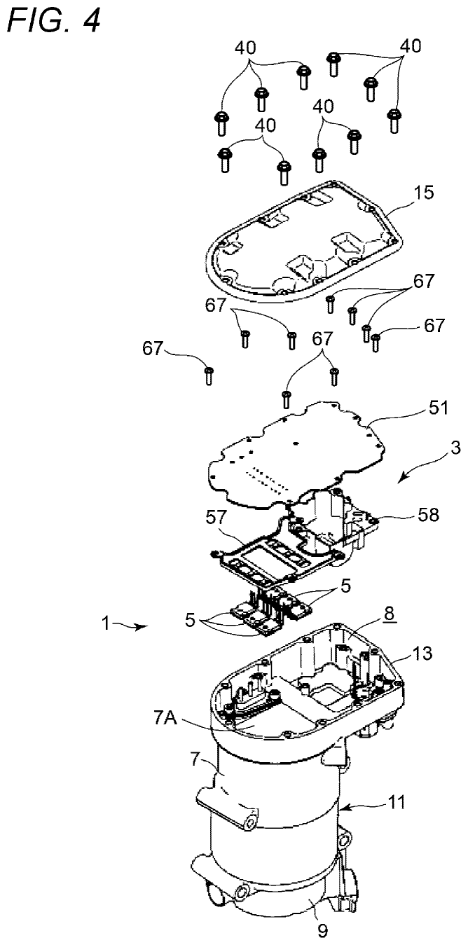

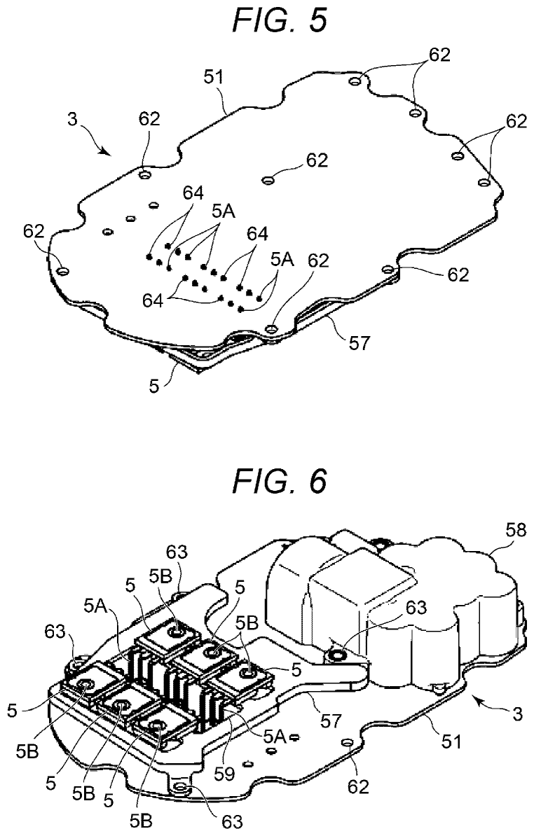

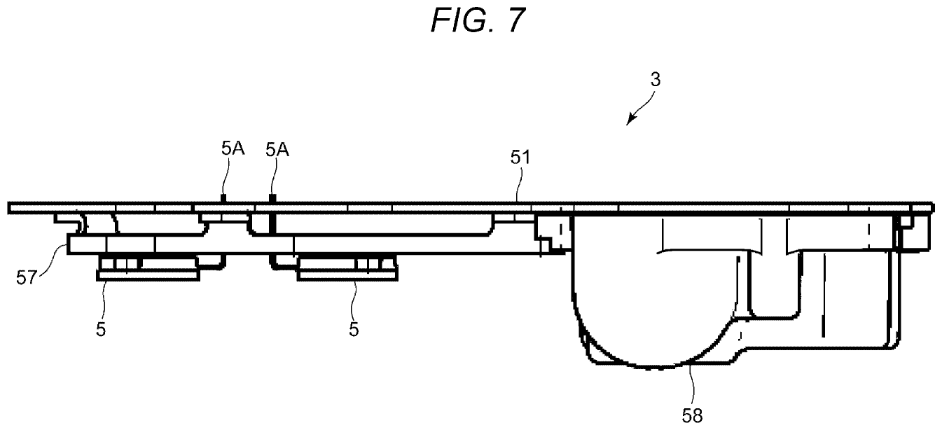

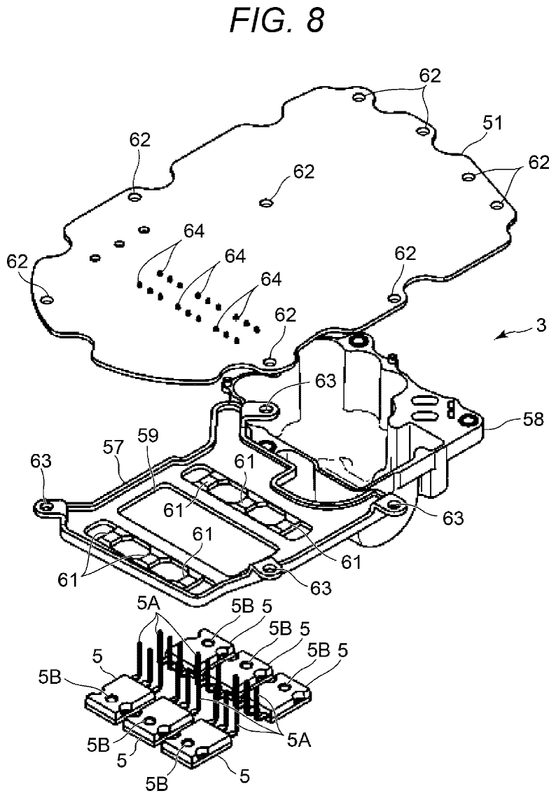

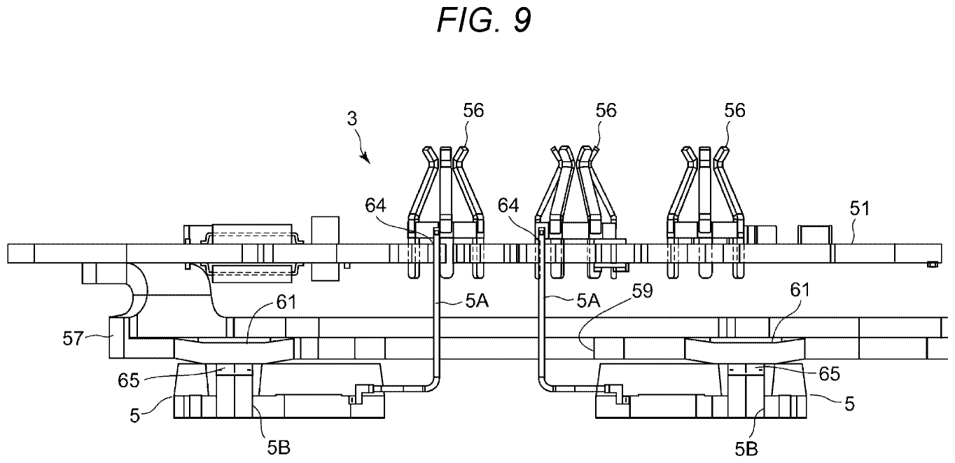

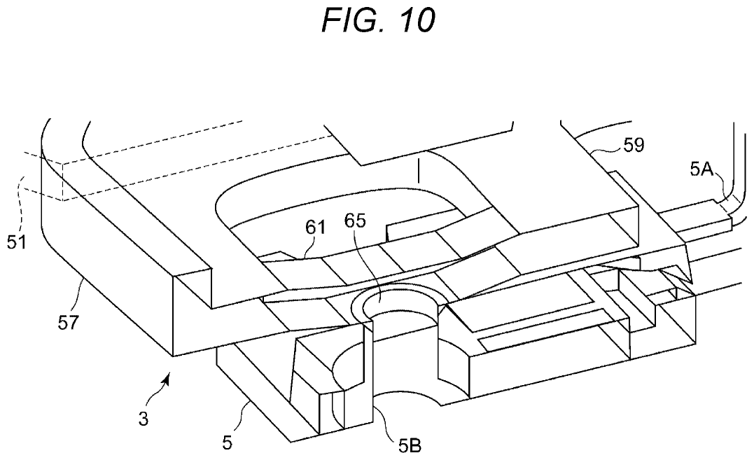

Next, the structure of the inverter 3 of the electric compressor 1 of the embodiment and a peripheral structure thereof will be described with further reference to FIGS. 4 to 10. Note that in FIGS. 2 and 3 described above and figures subsequent to FIG. 4, the housing 11 of the electric compressor 1 stands with the inverter accommodation portion 8 side as the upper side. FIG. 4 is an exploded perspective view of the electric compressor 1, FIG. 5 is a perspective view of the inverter 3 of the electric compressor 1 as viewed from the front surface thereof, FIG. 6 is a perspective view of the inverter 3 as viewed from the back surface thereof, FIG. 7 is a side view of the inverter 3, FIG. 8 is an exploded perspective view of the inverter 3, FIG. 9 is an enlarged sectional view of a switching element 5 of the inverter 3, and FIG. 10 is an enlarged perspective view of a main portion of FIG. 9.

### (2-1) Hermetic Plate 52 and Hermetic Pin 53

The inverter 3 of the embodiment is configured in such a manner that a control circuit is mounted on a single board 51 and a plurality of switching elements 5 (six in the embodiment) including IGBTs, a smoothing capacitor, and the like are connected thereto. Here, a hermetic plate 52 is attached to the end wall 7A (partition wall) of the main casing 7 as shown in FIG. 1, and a conductive hermetic pin 53 is attached to the hermetic plate 52.

In this case, three hermetic pins 53 are attached corresponding to each phase (three phases) of the electric motor 2. The other end side of each hermetic pin 53 penetrates the end wall 7A into the motor chamber 12, and is connected to the coil of the stator 25 of the electric motor 2.

On the other hand, one end side of each hermetic pin 53 stands so as to face the inside of the inverter accommodation portion 8. Three metal press-fit terminals 56 called power baskets are attached to the board 51 at the position corresponding to the other end side of each hermetic pin 53, and the one end side of each hermetic pin 53 enters a corresponding one of the press-fit terminals 56 and is pressure-welded (press-fitted) to such a press-fit terminal 56. Thus, it is configured such that each hermetic pin 53 is electrically connected to the board 51.

### (2-2) Structure of Inverter 3

Next, the structure of the inverter 3 will be described. The inverter 3 includes the above-described board 51, the above-described six switching elements 5, a fixing plate 57, and a filter case 58 accommodating the above-described smoothing capacitor. Among these components, the fixing plate 57 is disposed between the board 51 and each switching element 5, and has a function of pressing each switching element 5 against the end wall 7A of the main casing 7 (housing 11).

Here, in the embodiment, the six switching elements 5 are arranged three each in two lines as shown in FIG. 8. In addition, each switching element 5 has three terminals 5A, and the switching elements 5 in each line are arranged with the terminal 5A sides facing each other, and in this state, the terminals 5A of each switching element 5 stands toward the board 51. Further, each switching element 5 has a run-through hole (through-hole for attachment) 5B.

On the other hand, the fixing plate 57 is formed of a metal plate, and a terminal passing portion 59 through which the terminals 5A of each switching element 5 pass is formed so as to be opened in a substantially center portion. Further, on both sides of the terminal passing portion 59, a plurality of spring portions 61 (six in the embodiment) is formed at positions corresponding to the switching elements 5. As shown in FIGS. 9 and 10, each spring portion 61 has a strip shape in which only both ends in the longitudinal direction are continuous with the fixing plate 57 itself. Further, each spring portion 61 has an inverted trapezoidal ridgeline shape bent so as to protrude toward the switching element 5, and a positioning portion 65 protruding toward the switching element 5 is formed at a center portion of each protruding spring portion 61.

Each spring portion 61 has predetermined elasticity or spring properties due to the above-described bent shape, and generates biasing force for pressing the switching elements 5 against the end wall 7A of the main casing 7 (housing 11). As a result, the fixing plate 57 at least partially has spring properties. In a peripheral portion of the fixing plate 57, four fixing plate fastening portions (through-holes) 63 are formed so as to penetrate at positions corresponding to four of a plurality of board fastening portions (through-holes) 62 for fastening the board 51 to the main casing 7 (housing 11). Note that a reference numeral 64 denotes terminal connection portions formed in the board 51 at positions corresponding to the terminals 5A of each switching element 5.

### (3) Subassembly Procedure of Inverter 3

Next, a procedure for sub-assembling the inverter 3 having the above-described structure will be described. First, the six switching elements 5 are disposed on a jig (not illustrated) in the two lines as shown in FIG. 8. Next, the fixing plate 57 is placed on each switching element 5 in a state in which the terminals 5A of each switching element 5 are located in the terminal passing portion 59, each spring portion 61 corresponds to a corresponding one of the switching elements 5, and each positioning portion 65 enters and engages with a corresponding one of the run-through holes 5B.

Next, the board 51 is placed on the fixing plate 57 and the switching elements 5 in a state in which the four board fastening portions 62 of the board 51 are coincident with the respective fixing plate fastening portions 63 of the fixing plate 57. At this time, the terminals 5A of each switching element 5 pass through the terminal passing portion 59 of the fixing plate 57, and enter the terminal connection portions 64 of the board 51. Thereafter, the terminals 5A of each switching element 5 are soldered and fixed to the board 51, and each switching element 5 is electrically connected to the board 51. Note that the terminals 5A of the switching element 5 may be connected to the board 51 by press fitting.

In this state, the switching elements 5 are attached to the board 51, and the fixing plate 57 is positioned between the board 51 and the switching elements 5 and held by each switching element 5, whereby the inverter 3 is integrally assembled.

### (4) Procedure for Assembling Inverter 3 to Main Casing 7 (Housing 11)

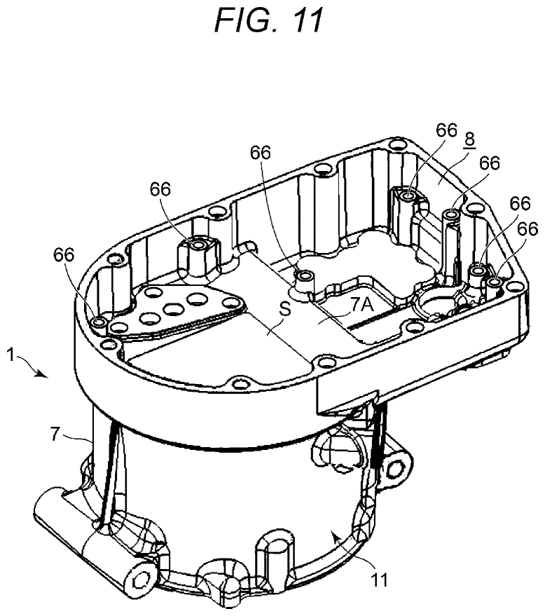

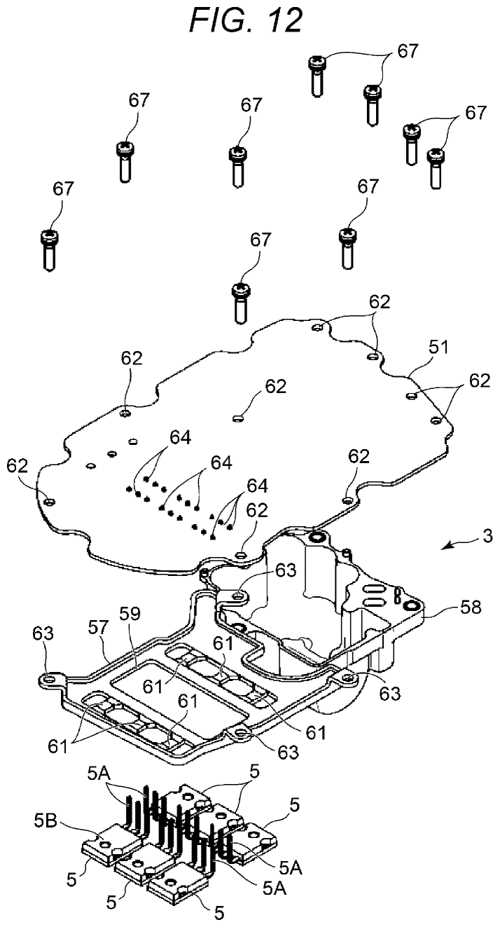

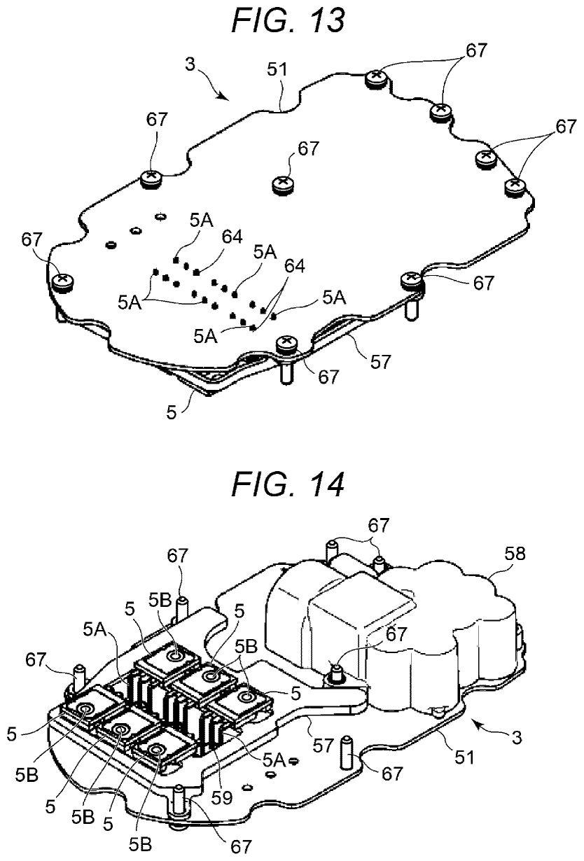

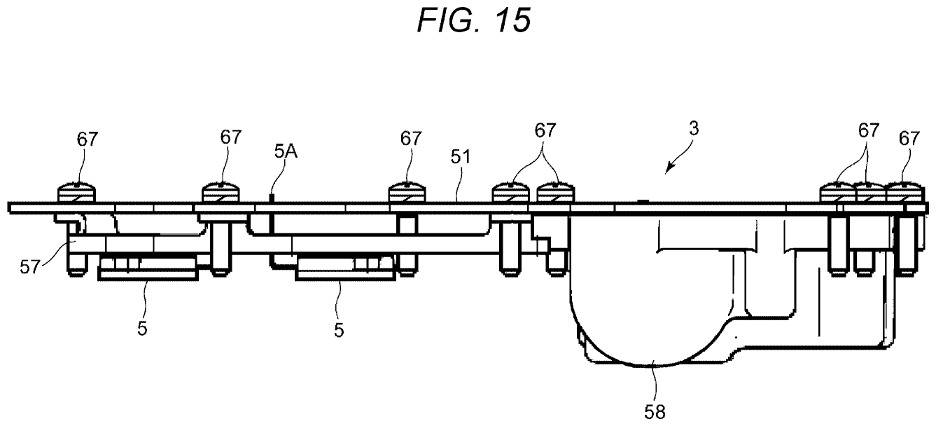

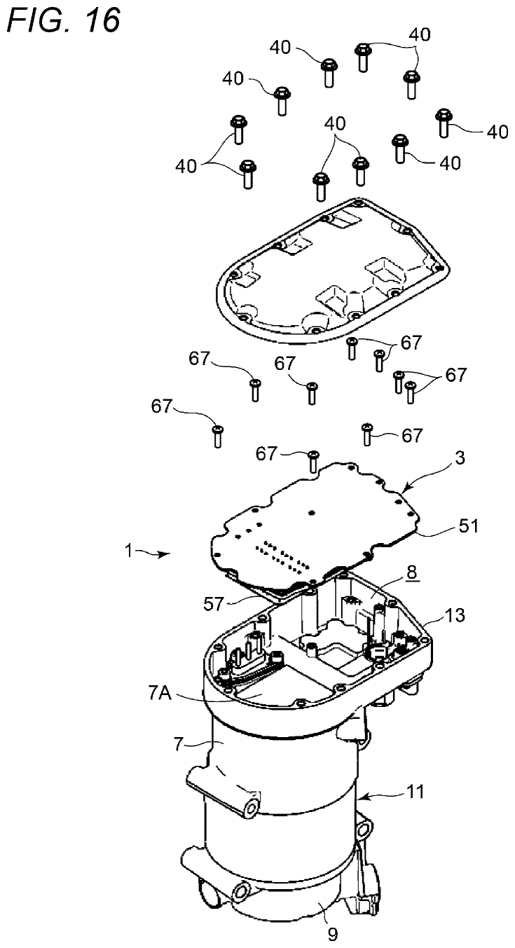

Next, a procedure for assembling the inverter 3 to the main casing 7 (housing 11) will be described with further reference to FIGS. 11 to 16. FIG. 11 is a perspective view of the inverter accommodation portion 8 of the housing 11, FIG. 12 is an exploded perspective view for describing a positional relationship between bolts 67 for fastening the inverter 3 to the main casing 7 (housing 11) and the inverter 3, FIG. 13 is a perspective view of the inverter 3 in a state of the bolts 67 being inserted thereinto as viewed from the front surface thereof, FIG. 14 is a perspective view of the inverter 3 of FIG. 13 as viewed from the back surface thereof, FIG. 15 is a side view of the inverter 3 of FIG. 13, and FIG. 16 is an exploded perspective view for describing a positional relationship between bolts 40 for fastening the inverter 3 and the lid member 15 of the electric compressor 1 to the main casing 7 (housing 11), the inverter 3, and the lid member 15.

In this case, in the inverter accommodation portion 8 of the main casing 7 (housing 11), fastening holes 66 are formed at positions corresponding to the board fastening portions 62 of the board 51 (FIG. 11). Then, as described above, the inverter 3 in which the switching elements 5, the fixing plate 57, and the board 51 are sub-assembled is inserted into the inverter accommodation portion 8 with the switching elements 5 on the end wall 7A side of the main casing 7 (housing 11) and disposed in the main casing 7 (housing 11).

Next, the bolts 67 (nine in the embodiment) as fasteners are inserted into the board fastening portions 62 of the board 51 and the fixing plate fastening portions 63 of the fixing plate 57, and are screwed into the fastening holes 66 of the main casing 7 (housing 11). As a result, the board 51 and the fixing plate 57 of the inverter 3 are assembled to the main casing 7 (housing 11) by co-fastening (state of FIG. 3).

In this state, each switching element 5 is pressed against the end wall 7A of the main casing 7 (housing 11) by the spring portions 61 of the fixing plate 57 with a predetermined load. Note that the pressing load in this case is adjusted by changing the free length of the spring portion 61 of the fixing plate 57 (dimension in the longitudinal direction of the strip shape).

In this manner, in a state of the inverter 3 being assembled to the main casing 7 (housing 11), the switching elements 5 are disposed on the outer surface (opposite to the motor chamber 12) of the end wall 7A of the main casing 7 (housing 11) in a relationship in which heat is exchangeable. Note that in practice, an insulating sheet (indicated by S in FIG. 11) or the like is interposed between the switching elements 5 and the end wall 7A. As a result, each switching element 5 is cooled with refrigerant sucked into the motor chamber 12 through the end wall 7A. That is, the main casing 7 (end wall 7A) forming the housing 11 serves as a heat sink for the switching element 5.

As described above in detail, according to the present invention, in the electric compressor 1 in which the board 51 to which the switching elements 5 are connected is assembled to the housing 11, the fixing plate 57 having spring properties and disposed between the switching elements 5 and the board 51 is provided, and the switching elements 5 are pressed against the housing 11 in a state of the fixing plate 57 being held by the switching elements 5 and the board 51 being assembled to the housing 11. Thus, the switching elements 5, the fixing plate 57, and the board 51 can be integrally assembled (sub-assembled) in advance with a simple configuration, these assembled components can be assembled to the housing 11, and in the assembled state, the switching elements 5 can be pressed against the housing 11 by the fixing plate 57.

As a result, it is possible to improve workability when the board 51 to which the switching elements 5 are connected is assembled to the housing 11 while reducing the number of components and a cost.

Since the fixing plate fastening portions 63 formed at the positions coincident with the board fastening portions 62 for fastening the board 51 to the housing 11 are formed in the fixing plate 57, and the spring portions 61 for biasing the switching elements 5 toward the housing 11 and the positioning portions 65 engaged with the switching elements 5 are provided in the fixing plate 57, the board 51 and the fixing plate 57 can be fastened to the housing 11 with the bolts 67 without any trouble, and the pressing of the switching elements 5 against the housing 11 by the fixing plate 57 and the holding of the fixing plate 57 by the switching elements 5 can be stably performed.

Since the positioning portions 65 of the fixing plate 57 are formed so as to protrude from the spring portions 61, and the positioning portions 65 are engaged with the run-through holes 5B of the switching elements 5, the fixing plate 57 is held by the switching elements 5. Thus, the pressing of the switching elements 5 against the housing 11 by the fixing plate 57 and the holding of the fixing plate 57 by the switching elements 5 can be performed with a simple configuration.

Since in the embodiment, the plurality of switching elements 5 is connected to the board 51, the plurality of spring portions 61 for biasing the switching elements 5 is formed in the fixing plate 57, and the positioning portions 65 are formed in the spring portions 61, each switching element 5 can be stably pressed against the housing 11. Moreover, since the terminal passing portion 59 through which the terminals 5A of each switching element 5 pass is provided in the fixing plate 57, the terminals 5A of each switching element 5 can be connected to the board 51 without any trouble.

Furthermore, since the load of pressing the switching elements 5 against the housing 11 is adjusted by changing the free length of the spring portions 61 of the fixing plate 57, the switching elements 5 can be safely and stably pressed against the housing 11 with a simple configuration.

Note that the specific shape of each member described in the embodiment is not limited to that of the embodiment, and can be changed without departing from the gist of the present invention.

In particular, in the embodiment, the spring portions 61 are formed in the fixing plate 57 so that the fixing plate 57 partially has the spring properties, but the invention of claim 1 is not limited thereto, and the fixing plate 57 itself may be formed of a spring (for example, leaf spring) and the entire fixing plate 57 may have spring properties. In this case, the positioning portions 65 may be formed at the positions corresponding to the switching elements 5 in the fixing plate 57. The adjustment of the biasing force for pressing the switching elements 5 against the end wall 7A of the main casing 7 (housing 11) also adjusts the rigidity of the fixing plate 57.

In the embodiment, the bent spring portions 61 are formed in the fixing plate 57, but the present invention is not limited thereto, and a spring such as a leaf spring may be separately attached to the fixing plate 57 to impart spring properties to part of the fixing plate 57. In this case, for example, the positioning portions 65 and the fixing plate 57 are provided as separate members, and are coupled with springs (leaf springs), and the springs or the like and the positioning portions 65 form the spring portions 61 in the present invention. Then, the switching elements 5 may be pressed against the end wall 7A of the main casing 7 (housing 11) by the springs or the like.

Furthermore, in the embodiment, the positioning portions 65 are formed in the spring portions 61, but the invention other than claims 3 and 4 is not limited thereto, and for example, the spring portions 61 may be formed in the fixing plate 57 at positions other than the positions corresponding to the switching elements 5, or springs may be separately attached to form the positioning portions 65 at a position corresponding to each switching element 5.

### LIST OF REFERENCE SIGNS

1 Electric Compressor
2 Electric Motor (Motor)
3 Inverter
4 Scroll Compression Mechanism (Compression Mechanism)
5 Switching Element
5A Terminal
5B Run-Through Hole
7 Main Casing
7A End Wall
8 Inverter Accommodation Portion
11 Housing
12 Motor Chamber
51 Board
57 Fixing Plate
59 Terminal Passing Portion
61 Spring Portion
62 Board Fastening Portion
63 Fixing Plate Fastening Portion
65 Positioning Portion
67 Bolt (Fastener)

1. An electric compressor in which a board to which a switching element is connected is assembled to a housing, comprising:
a fixing plate disposed between the switching element and the board and entirely or at least partially having a spring property,
wherein the fixing plate is held by the switching element, and presses the switching element against the housing in a state of the board being assembled to the housing.

2. The electric compressor according to claim 1, wherein
the board has a board fastening portion for fastening the board to the housing, and
the fixing plate has a fixing plate fastening portion formed at a position coincident with the board fastening portion, a spring portion for biasing the switching element toward the housing, and a positioning portion engaged with the switching element.

3. The electric compressor according to claim 2, wherein
the positioning portion is formed so as to protrude from the spring portion, and
the fixing plate is held by the switching element by engaging the positioning portion with a run-through hole of the switching element.

4. The electric compressor according to claim 3, wherein
a plurality of the switching elements is connected to the board, and
the fixing plate has a plurality of the spring portions biasing the switching elements respectively, the positioning portion formed in each spring portion, and a terminal passing portion through which terminals of the switching elements pass.

5. A method for producing an electric compressor in which a board to which a switching element is connected is assembled to a housing, the method comprising:
preparing a fixing plate having a spring portion for biasing the switching element toward the housing, a positioning portion engaged with the switching element, a terminal passing portion through which a terminal of the switching element passes, and a fixing plate fastening portion;
disposing the fixing plate between the switching element and the board; and
integrally assembling the switching element, the fixing plate, and the board by connecting the terminal of the switching element, which has passed through the terminal passing portion of the fixing plate, to the board in a state of the positioning portion of the fixing plate being engaged with a run-through hole of the switching element and the fixing plate fastening portion of the fixing plate being coincident with a board fastening portion of the board.

6. The method for producing the electric compressor according to claim 5, further comprising:
after the assembled switching element, fixing plate, and board have been disposed in the housing with the switching element on a housing side,
inserting a fastener into the board fastening portion and the fixing plate fastening portion; and
assembling the board and the fixing plate to the housing by co-fastening by screwing the fastener into the housing, and pressing the switching element against the housing by the spring portion of the fixing plate.

7. The method for producing the electric compressor according to claim 6, wherein a load of pressing the switching element against the housing is adjusted by changing a free length of the spring portion of the fixing plate or adjusting rigidity of the fixing plate.
